(19) United States
(12) Patent Application Publication
(10) Pub. No.: US 2014/0264465 A1
(43) Pub. Date: Sep. 18, 2014

(54) CHEMICAL SENSORS WITH PARTIALLY EXTENDED SENSOR SURFACES

(71) Applicant: LIFE TECHNOLOGIES CORPORATION, Carlsbad, CA (US)

(72) Inventors: Keith Fife, Palo Alto, CA (US); James Bustillo, Castro Valley, CA (US); Jordan Owens, Austin, TX (US)

(73) Assignee: Life Technologies Corporation, Carlsbad, CA (US)

(21) Appl. No.: 13/801,112

(22) Filed: Mar. 13, 2013

(51) Int. Cl. G01N 27/414; H01L 29/788; H01L 29/66

(52) U.S. Cl. CPC G01N 27/414; H01L 29/66825; H01L 29/788
USPC 257/253; 438/49

(57) ABSTRACT

In one implementation, a chemical sensor is described. The chemical sensor includes a chemically-sensitive field effect transistor including a floating gate conductor having an upper surface. A dielectric material defines an opening extending to the upper surface of the floating gate conductor. A conductive element is on a sidewall of the opening and spaced away from an upper surface of the dielectric material, the conductive element communicating with the floating gate conductor.

### BACKGROUND

The present disclosure relates to sensors for chemical analysis, and to methods for manufacturing such sensors.

A variety of types of chemical sensors have been used in the detection of chemical processes. One type is a chemically-sensitive field effect transistor (chemFET). A chemFET includes a source and a drain separated by a channel region, and a chemically sensitive area coupled to the channel region. The operation of the chemFET is based on the modulation of channel conductance, caused by changes in charge at the sensitive area due to a chemical reaction occurring nearby. The modulation of the channel conductance changes the threshold voltage of the chemFET, which can be measured to detect and/or determine characteristics of the chemical reaction. The threshold voltage may for example be measured by applying appropriate bias voltages to the source and drain, and measuring a resulting current flowing through the chemFET. As another example, the threshold voltage may be measured by driving a known current through the chemFET, and measuring a resulting voltage at the source or drain.

An ion-sensitive field effect transistor (ISFET) is a type of chemFET that includes an ion-sensitive layer at the sensitive area. The presence of ions in an analyte solution alters the surface potential at the interface between the ion-sensitive layer and the analyte solution, due to the protonation or deprotonation of surface charge groups caused by the ions present in the analyte solution. The change in surface potential at the sensitive area of the ISFET affects the threshold voltage of the device, which can be measured to indicate the presence and/or concentration of ions within the solution.

Arrays of ISFETs may be used for monitoring chemical reactions, such as DNA sequencing reactions, based on the detection of ions present, generated, or used during the reactions. See, for example, U.S. Pat. No. 7,948,015 to Rothberg et al., which is incorporated by reference herein. More generally, large arrays of chemFETs or other types of chemical sensors may be employed to detect and measure static and/or dynamic amounts or concentrations of a variety of analytes (e.g. hydrogen ions, other ions, compounds, etc.) in a variety of processes. The processes may for example be biological or chemical reactions, cell or tissue cultures or monitoring neural activity, nucleic acid sequencing, etc.

An issue that arises in the operation of large scale chemical sensor arrays is the susceptibility of the sensor output signals to noise. Specifically, the noise affects the accuracy of the downstream signal processing used to determine the characteristics of the chemical and/or biological process being detected by the sensors.

It is therefore desirable to provide devices including low noise chemical sensors, and methods for manufacturing such devices.

### SUMMARY

In one implementation, a chemical sensor is described. The chemical sensor includes a chemically-sensitive field effect transistor including a floating gate conductor having an upper surface. A dielectric material defines an opening extending to the upper surface of the floating gate conductor. A conductive element is on a sidewall of the opening and spaced away from an upper surface of the dielectric material, the conductive element communicating with the floating gate conductor.

In another implementation, a method for manufacturing a chemical sensor is described. The method includes forming a chemically-sensitive field effect transistor including a floating gate conductor having an upper surface. The method also includes forming a dielectric material defining an opening extending to the upper surface of the floating gate conductor. The method also includes forming a conductive layer on a sidewall of the opening and spaced away from an upper surface of the dielectric material, the conductive layer communicating with the floating gate conductor.

Particular aspects of one more implementations of the subject matter described in this specification are set forth in the drawings and the description below. Other features, aspects, and advantages of the subject matter will become apparent from the description, the drawings, and the claims.

### BRIEF DESCRIPTION OF THE DRAWINGS

FIG. 1 illustrates a block diagram of components of a system for nucleic acid sequencing according to an exemplary embodiment.

FIG. 2 illustrates a cross-sectional view of a portion of the integrated circuit device and flow cell according to an exemplary embodiment.

FIGS. 3A and 3B illustrate cross-sectional and plan views respectively of a representative chemical sensors and corresponding reaction regions according to an exemplary embodiment.

FIGS. 4 to 10 illustrate stages in a manufacturing process for forming an array of chemical sensors and corresponding well structures according to an exemplary embodiment.

### DETAILED DESCRIPTION

A chemical detection device is described that includes low noise chemical sensors, such as chemically-sensitive field effect transistors (chemFETs), for detecting chemical reactions within overlying, operationally associated reaction regions.

Reducing the plan or top view area (or footprint) of individual chemical sensors and the overlying reaction regions allows for higher density devices. However, as the dimensions of the chemical sensors are reduced, Applicants have found that a corresponding reduction in the sensing surface area of the sensors can significantly reduce sensor performance.

For example, for chemical sensors having sensing surfaces defined at the bottom of the reaction regions, reducing the plan view dimensions (e.g. the width or diameter) of the reaction regions results in a similar reduction in the sensing surface areas. Applicants have found that as the sensing surface area is reduced to technology limits, fluidic noise due to the random fluctuation of charge on the sensing surface contributes to an increasing proportion of the total variation in sensing surface potential. This can significantly reduce the signal-to-noise ratio (SNR) of the sensor output signal, which affects the accuracy of the downstream signal processing used to determine the characteristics of the chemical and/or biological process being detected by the sensor.

Chemical sensors described herein have sensing surface areas which are not limited to a two-dimensional area at the bottom of the reaction regions. In embodiments described herein, the sensing surface of the chemical sensor includes a generally horizontal portion along the bottom surface of the reaction region, as well as a generally vertical portion extending up a sidewall of the reaction region.

By extending the sensing surface in generally vertical direction, the chemical sensor can have a small footprint, while also having a sufficiently large sensing surface area to avoid the noise issues associated with small sensing surfaces. The footprint of a chemical sensor is determined in part by the width (e.g. diameter) of the overlying reaction region and can be made small, allowing for a high density array. In addition, because the sensing surface extends up the sidewall, the sensing surface area can be relatively large. As a result, low noise chemical sensors can be provided in a high density array, such that the characteristics of reactions can be accurately detected.

FIG. 1 illustrates a block diagram of components of a system for nucleic acid sequencing according to an exemplary embodiment. The components include a flow cell 101 on an integrated circuit device 100, a reference electrode 108, a plurality of reagents 114 for sequencing, a valve block 116, a wash solution 110, a valve 112, a fluidics controller 118, lines 120/122/126, passages 104/109/111, a waste container 106, an array controller 124, and a user interface 128. The integrated circuit device 100 includes a microwell array 107 overlying a sensor array that includes chemical sensors as described herein. The flow cell 101 includes an inlet 102, an outlet 103, and a flow chamber 105 defining a flow path of reagents over the microwell array 107.

The reference electrode 108 may be of any suitable type or shape, including a concentric cylinder with a fluid passage or a wire inserted into a lumen of passage 111. The reagents 114 may be driven through the fluid pathways, valves, and flow cell 101 by pumps, gas pressure, or other suitable methods, and may be discarded into the waste container 106 after exiting the outlet 103 of the flow cell 101. The fluidics controller 118 may control driving forces for the reagents 114 and the operation of valve 112 and valve block 116 with suitable software.

The microwell array 107 includes an array of reaction regions as described herein, also referred to herein as microwells, which are operationally associated with corresponding chemical sensors in the sensor array. For example, each reaction region may be coupled to a chemical sensor suitable for detecting an analyte or reaction property of interest within that reaction region. The microwell array 107 may be integrated in the integrated circuit device 100, so that the microwell array 107 and the sensor array are part of a single device or chip.

The flow cell 101 may have a variety of configurations for controlling the path and flow rate of reagents 114 over the microwell array 107. The array controller 124 provides bias voltages and timing and control signals to the integrated circuit device 100 for reading the chemical sensors of the sensor array. The array controller 124 also provides a reference bias voltage to the reference electrode 108 to bias the reagents 114 flowing over the microwell array 107.

During an experiment, the array controller 124 collects and processes output signals from the chemical sensors of the sensor array through output ports on the integrated circuit device 100 via bus 127. The array controller 124 may be a computer or other computing means. The array controller 124 may include memory for storage of data and software applications, a processor for accessing data and executing applications, and components that facilitate communication with the various components of the system in FIG. 1.

The values of the output signals of the chemical sensors indicate physical and/or chemical parameters of one or more reactions taking place in the corresponding reaction regions in the microwell array 107. For example, in an exemplary embodiment, the values of the output signals may be processed using the techniques disclosed in Rearick et al., U.S. patent application Ser. No. 13/339,846, filed Dec. 29, 2011, based on U.S. Prov. Pat. Appl. Nos. 61/428,743, filed Dec. 30, 2010, and 61/429,328, filed Jan. 3, 2011, and in Hubbell, U.S. patent application Ser. No. 13/339,753, filed Dec. 29, 2011, based on U.S. Prov. Pat. Appl. No. 61/428,097, filed Dec. 29, 2010, which are all incorporated by reference herein in their entirety.

The user interface 128 may display information about the flow cell 101 and the output signals received from chemical sensors in the sensor array on the integrated circuit device 100. The user interface 128 may also display instrument settings and controls, and allow a user to enter or set instrument settings and controls.

In an exemplary embodiment, during the experiment the fluidics controller 118 may control delivery of the individual reagents 114 to the flow cell 101 and integrated circuit device 100 in a predetermined sequence, for predetermined durations, at predetermined flow rates. The array controller 124 can then collect and analyze the output signals of the chemical sensors indicating chemical reactions occurring in response to the delivery of the reagents 114.

During the experiment, the system may also monitor and control the temperature of the integrated circuit device 100, so that reactions take place and measurements are made at a known predetermined temperature.

The system may be configured to let a single fluid or reagent contact the reference electrode 108 throughout an entire multi-step reaction during operation. The valve 112 may be shut to prevent any wash solution 110 from flowing into passage 109 as the reagents 114 are flowing. Although the flow of wash solution may be stopped, there may still be uninterrupted fluid and electrical communication between the reference electrode 108, passage 109, and the microwell array 107. The distance between the reference electrode 108 and the junction between passages 109 and 111 may be selected so that little or no amount of the reagents flowing in passage 109 and possibly diffusing into passage 111 reach the reference electrode 108. In an exemplary embodiment, the wash solution 110 may be selected as being in continuous contact with the reference electrode 108, which may be especially useful for multi-step reactions using frequent wash steps.

FIG. 2 illustrates cross-sectional and expanded views of a portion of the integrated circuit device 100 and flow cell 101. During operation, the flow chamber 105 of the flow cell 101 confines a reagent flow 208 of delivered reagents across open ends of the reaction regions in the microwell array 107. The volume, shape, aspect ratio (such as base width-to-well depth ratio), and other dimensional characteristics of the reaction regions may be selected based on the nature of the reaction taking place, as well as the reagents, byproducts, or labeling techniques (if any) that are employed.

The chemical sensors of the sensor array 205 are responsive to (and generate output signals) chemical reactions within associated reaction regions in the microwell array 107 to detect an analyte or reaction property of interest. The chemical sensors of the sensor array 205 may for example be chemically sensitive field-effect transistors (chemFETs), such as ion-sensitive field effect transistors (ISFETs). Examples of chemical sensors and array configurations that may be used in embodiments are described in U.S. Patent Application Publication No. 2010/0300559, No. 2010/0197507, No. 2010/0301398, No. 2010/0300895, No. 2010/0137143, and No. 2009/0026082, and U.S. Pat. No. 7,575,865, each which are incorporated by reference herein.

FIG. 3A illustrates a cross-sectional view of two representative chemical sensors and their corresponding reaction regions according to an exemplary embodiment. In FIG. 3, two chemical sensors 350, 351 are shown, representing a small portion of a sensor array that can include millions of chemical sensors.

Chemical sensor 350 is coupled to corresponding reaction region 301, and chemical sensor 351 is coupled to corresponding reaction region 302. Chemical sensor 350 is representative of the chemical sensors in the sensor array. In the illustrated example, the chemical sensor 350 is a chemically-sensitive field effect transistor (chemFET), more specifically an ion-sensitive field effect transistor (ISFET) in this example.

The chemical sensor 350 includes a floating gate structure 318 having a sensor plate 320 coupled to the reaction region 301 by an electrically conductive element 370. As can be seen in FIG. 3A, the sensor plate 320 is the uppermost floating gate conductor in the floating gate structure 318. In the illustrated example, the floating gate structure 318 includes multiple patterned layers of conductive material within layers of dielectric material 319.

The chemical sensor 350 also includes a source region 321 and a drain region 322 within a semiconductor substrate 354. The source region 321 and the drain region 322 comprise doped semiconductor material have a conductivity type different from the conductivity type of the substrate 354. For example, the source region 321 and the drain region 322 may comprise doped P-type semiconductor material, and the substrate may comprise doped N-type semiconductor material.

Channel region 323 separates the source region 321 and the drain region 322. The floating gate structure 318 overlies the channel region 323, and is separated from the substrate 354 by a gate dielectric 352. The gate dielectric 352 may be for example silicon dioxide. Alternatively, other dielectrics may be used for the gate dielectric 352.

As shown in FIG. 3A, the reaction region 301 is within a opening having a sidewall 303 extending through dielectric material 310 to the upper surface of the sensor plate 320. The dielectric material 310 may comprise one or more layers of material, such as silicon dioxide or silicon nitride. The opening includes a lower portion 314 proximate to the sensor plate 320. The opening also includes an upper portion 315 extending from the lower portion 314 to the upper surface 311 of the dielectric material 310.

The dimensions of the openings, and their pitch, can vary from implementation to implementation. In some embodiments, the openings can have a characteristic diameter, defined as the square root of 4 times the plan view cross-sectional area (A) divided by Pi (e.g., sqrt(4*A/π), of not greater than 5 micrometers, such as not greater than 3.5 micrometers, not greater than 2.0 micrometers, not greater than 1.6 micrometers, not greater than 1.0 micrometers, not greater than 0.8 micrometers, not greater than 0.6 micrometers, not greater than 0.4 micrometers, not greater than 0.2 micrometers or even not greater than 0.1 micrometers.

The lower portion 314 of the opening includes the electrically conductive element 370 on the sidewall 303 of the dielectric material 310. In the illustrated embodiment, the inner surface 371 of the electrically conductive element 370 defines a lower segment of the reaction region 301. That is, there is no intervening deposited material layer between the inner surface 371 of the electrically conductive element 370 and the reaction region 301 for the chemical sensor 350. In the illustrated embodiment, the electrically conductive element 370 is a conformal layer of material within the lower portion 314 of the opening, such that the electrically conductive element 370 extends across the upper surface of the sensor plate 320. As a result of this structure, the inner surface 371 of the electrically conductive element 370 is cup-shaped and acts as the sensing surface for the chemical sensor 350.

As shown in FIG. 3A, the electrically conductive element 370 does not extend into the upper portion 315 of the opening. Instead, the electrically conductive element 370 is spaced away from the upper surface 311 of the dielectric material 310 by the upper portion 315 of the opening. The conductive element 370 may for example extend along at least 5% of the sidewall 303, at least 10%, at least 25%, at least 50%, at least 75%, or even at least 85% of the sidewall 303. As a result, an upper segment of the reaction region 301 is defined by sidewall 303 in the upper portion 315 of the opening, and has a different width than the lower segment.

The cup-shaped inner surface 371 of the electrically conductive element 370 allows the chemical sensor 350 to have a small plan view area, while also having a sufficiently large surface area to avoid the noise issues associated with small sensing surfaces. The plan view area of the chemical sensor is determined in part by the width (or diameter) of the reaction region 301 and can be made small, allowing for a high density array. In addition, because the sensing surface extends up the sidewall 303, the sensing surface area depends upon the distance of this extension and the circumference of the reaction region 301, and can be relatively large. As a result, low noise chemical sensors 350, 351 can be provided in a high density array, such that the characteristics of reactions can be accurately detected.

During manufacturing and/or operation of the device, a thin oxide of the material of the electrically conductive element 370 may be grown which acts as a sensing material (e.g. an ion-sensitive sensing material) for the chemical sensor 350. Whether an oxide is formed depends on the conductive material, the manufacturing processes performed, and the conditions under which the device is operated. For example, in one embodiment the conductive element 370 may be titanium nitride, and titanium oxide or titanium oxynitride may be grown on the inner surface 371 of the conductive element 370 during manufacturing and/or during exposure to solutions during use.

In the illustrate example, the conductive element 370 is shown as a single layer of material. More generally, the conductive element 370 may comprise one or more layers of a variety of electrically conductive materials, such as metals or ceramics, depending upon the implementation. The conductive material can be for example a metallic material or alloy thereof, or can be a ceramic material, or a combination thereof. An exemplary metallic material includes one of aluminum, copper, nickel, titanium, silver, gold, platinum, hafnium, lanthanum, tantalum, tungsten, iridium, zirconium, palladium, or a combination thereof. An exemplary ceramic material includes one of titanium nitride, titanium aluminum nitride, titanium oxynitride, tantalum nitride or a combination thereof.

In some alternative embodiments, an additional conformal sensing material (not shown) is deposited on the conductive element 370. The sensing material may comprise one or more of a variety of different materials to facilitate sensitivity to particular ions. For example, silicon nitride or silicon oxynitride, as well as metal oxides such as silicon oxide, aluminum or tantalum oxides, generally provide sensitivity to hydrogen ions, whereas sensing materials comprising polyvinyl chloride containing valinomycin provide sensitivity to potassium ions. Materials sensitive to other ions such as sodium, silver, iron, bromine, iodine, calcium, and nitrate may also be used, depending upon the implementation.

As shown in the plan view of FIG. 3B, in the illustrated example the opening and the reaction region 301 have circular cross sections. Alternatively, these may be non-circular. For example, the cross-section may be square, rectangular, hexagonal, or irregularly shaped.

Referring back to FIG. 3A, in operation, reactants, wash solutions, and other reagents may move in and out of the reaction region 301 by a diffusion mechanism 340. The chemical sensor 350 is responsive to (and generates an output signal related to) the amount of a charge 324 proximate to the conductive element 370. The presence of charge 324 in an analyte solution alters the surface potential at the interface between the conductive element 370 and the analyte solution. Changes in the charge 324 cause changes in the voltage on the floating gate structure 318, which in turn changes in the threshold voltage of the transistor. This change in threshold voltage can be measured by measuring the current in the channel region 323 between the source region 321 and a drain region 322. As a result, the chemical sensor 350 can be used directly to provide a current-based output signal on an array line connected to the source region 321 or drain region 322, or indirectly with additional circuitry to provide a voltage-based output signal.

Because the charge 324 is more highly concentrated near the bottom of the reaction region 301, the distance that the conductive element 370 extends up the sidewall 303 of the opening is a tradeoff between the amplitude of the desired signal detected in response to the charge 324, and the fluidic noise due to random fluctuation of charge between the conductive element 370 and the analyte solution. Increasing the distance that the conductive element 370 extends up the sidewall 303 increases the fluidic interface area for the chemical sensor 350, which reduces the fluidic noise. However, since the surface density of the charge 324 decreases with distance from the bottom of the reaction region 301, upper portions of the conductive element 370 detect portions of the signal from areas having lower charge concentration, which can reduce the overall amplitude of the desired signal detected by the sensor 350. In contrast, decreasing the distance the conductive element 370 extends up the sidewall 303 reduces the sensing surface area and thus increases the fluidic noise, but also increases the overall amplitude of the desired signal detected by the sensor 350.

For a very small sensing surface area, Applicants have found that the fluidic noise changes as a function of the sensing surface area differently than the amplitude of the desired signal. Because the SNR of the sensor output signal is the ratio of these two quantities, there is an optimal distance the conductive element 370 extends up the sidewall 303 at which SNR is maximum.

The optimal distance can vary from embodiment to embodiment depending on the material characteristics of the conductive element 370 and the dielectric material 310, the volume, shape, aspect ratio (such as base width-to-well depth ratio), and other dimensional characteristics of the reaction regions, the nature of the reaction taking place, as well as the reagents, byproducts, or labeling techniques (if any) that are employed. The optimal distance may for example be determined empirically.

In an embodiment, reactions carried out in the reaction region 301 can be analytical reactions to identify or determine characteristics or properties of an analyte of interest. Such reactions can generate directly or indirectly byproducts that affect the amount of charge adjacent to the sensor plate 320. If such byproducts are produced in small amounts or rapidly decay or react with other constituents, multiple copies of the same analyte may be analyzed in the reaction region 301 at the same time in order to increase the output signal generated. In an embodiment, multiple copies of an analyte may be attached to a solid phase support 312, either before or after deposition into the reaction region 301. The solid phase support 312 may be microparticles, nanoparticles, beads, solid or porous comprising gels, or the like. For simplicity and ease of explanation, solid phase support 312 is also referred herein as a particle. For a nucleic acid analyte, multiple, connected copies may be made by rolling circle amplification (RCA), exponential RCA, or like techniques, to produce an amplicon without the need of a solid support.

In various exemplary embodiments, the methods, systems, and computer readable media described herein may advantageously be used to process and/or analyze data and signals obtained from electronic or charged-based nucleic acid sequencing. In electronic or charged-based sequencing (such as, pH-based sequencing), a nucleotide incorporation event may be determined by detecting ions (e.g., hydrogen ions) that are generated as natural by-products of polymerase-catalyzed nucleotide extension reactions. This may be used to sequence a sample or template nucleic acid, which may be a fragment of a nucleic acid sequence of interest, for example, and which may be directly or indirectly attached as a clonal population to a solid support, such as a particle, microparticle, bead, etc. The sample or template nucleic acid may be operably associated to a primer and polymerase and may be subjected to repeated cycles or “flows” of deoxynucleoside triphosphate (“dNTP”) addition (which may be referred to herein as “nucleotide flows” from which nucleotide incorporations may result) and washing. The primer may be annealed to the sample or template so that the primer's 3′ end can be extended by a polymerase whenever dNTPs complementary to the next base in the template are added. Then, based on the known sequence of nucleotide flows and on measured output signals of the chemical sensors indicative of ion concentration during each nucleotide flow, the identity of the type, sequence and number of nucleotide(s) associated with a sample nucleic acid present in a reaction region coupled to a chemical sensor can be determined.

FIGS. 4 to 10 illustrate stages in a manufacturing process for forming an array of chemical sensors and corresponding well structures according to an exemplary embodiment.

FIG. 4 illustrates a first stage of forming a structure including a dielectric material 310 on the sensor plate 320 of the field effect transistor of the chemical sensor 350. The structure in FIG. 4 can be formed by depositing a layer of gate dielectric material on the semiconductor substrate 354, and depositing a layer of polysilicon (or other electrically conductive material) on the layer of gate dielectric material. The layer of polysilicon and the layer gate dielectric material can then be etched using an etch mask to form the gate dielectric elements (e.g. gate dielectric 352) and the lowermost conductive material element of the floating gate structures. Following formation of an ion-implantation mask, ion implantation can then be performed to form the source and drain regions (e.g. source region 321 and a drain region 322) of the chemical sensors.

A first layer of the dielectric material 319 can then be deposited over the lowermost conductive material elements. Conductive plugs can then be formed within vias etched in the first layer of dielectric material 319 to contact the lowermost conductive material elements of the floating gate structures. A layer of conductive material can then be deposited on the first layer of the dielectric material 319 and patterned to form second conductive material elements electrically connected to the conductive plugs. This process can then be repeated multiple times to form the completed floating gate structure 318 shown in FIG. 4. Alternatively, other and/or additional techniques may be performed to form the structure.

Forming the structure in FIG. 4 can also include forming additional elements such as array lines (e.g. word lines, bit lines, etc.) for accessing the chemical sensors, additional doped regions in the substrate 354, and other circuitry (e.g. access circuitry, bias circuitry etc.) used to operate the chemical sensors, depending upon the device and array configuration in which the chemical sensors described herein are implemented. In some embodiments, the elements of the structure may for example be manufactured using techniques described in U.S. Patent Application Publication No. 2010/0300559, No. 2010/0197507, No. 2010/0301398, No. 2010/0300895, No. 2010/0137143, and No. 2009/0026082, and U.S. Pat. No. 7,575,865, each which are incorporated by reference herein.

Next, the dielectric material 310 of the structure in FIG. 4 is etched to form openings 500, 502 extending to the upper surfaces of the floating gate structures of the chemical sensors 350, 351, resulting in the structure illustrated in FIG. 5.

The openings 500, 502 may for example be formed by using a lithographic process to pattern a layer of photoresist on the dielectric material 310 to define the locations of the openings 500, 502, and then anisotropically etching the dielectric material 310 using the patterned photoreist as an etch mask. The anisotropic etching of the dielectric material 310 may for example be a dry etch process, such as a fluorine based Reactive Ion Etching (RIE) process.

In the illustrated embodiment, the openings 500, 502 are separated by a distance that 530 that is equal to their width 520. Alternatively, the separation distance 530 between adjacent openings may be less than the width 520. For example, the separation distance 530 may be a minimum feature size for the process (e.g. a lithographic process) used to form the openings 500, 502. In such a case, the distance 530 may be significantly less than the width 520.

Next, a conformal layer of conductive material 600 is deposited on the structure illustrated in FIG. 5, resulting in the structure illustrated in FIG. 6. The conductive material 600 comprises one or more layers of electrically conductive material. For example, the conductive material 500 may be a layer of titanium nitride, or a layer of titanium. Alternatively, other and/or additional conductive materials may be used, such as those described above with reference to the conductive element 370. In addition, more than one layer of conductive material may be deposited.

The conductive material 600 may be deposited using various techniques, such as sputtering, reactive sputtering, atomic layer deposition (ALD), low pressure chemical vapor deposition (LPCVD), plasma enhanced chemical vapor deposition (PECVD), metal organic chemical vapor deposition (MOCVD), etc.

Next, a fill material 700 is formed on the structure illustrated in FIG. 6, resulting in the structure illustrated in FIG. 7. The fill material 310 may comprise one or more layers of material, and may be deposited using various techniques. For example, the fill material 700 may be a layer of photoresist, polymer-based anti-reflective coating, polyimide, etc. The fill material 700 may be deposited using various techniques, such as spin coating, spray coating, etc. The fill material 700 and the conductive material 600 each comprise material which can be selectively removed relative to one another, and relative to the dielectric material 310. For example, in one embodiment the fill material 700 is photoresist and can be selectively removed using oxygen plasma etching, the conductive material 600 is titanium and can be selectively removed using ammonium hydroxide, hydrogen peroxide, and water, and the dielectric material 310 is silicon dioxide.

Next, the fill material 700 is partially etched to expose the conductive material 600 on the upper surface 311 of the dielectric material 310 and on the sidewalls of the upper portions of the openings 500, 502, resulting in the structure illustrated in FIG. 8. The partial etch process leaves remaining fill material elements 702, 704 within lower portions of the openings 500, 502.

The etching process may for example use end point detection to determine when the conductive material 600 on the upper surface 311 of the dielectric material 310 is exposed, followed by a timed etch so that the removal of the fill material 700 can be stopped a desired distance into the openings 500, 502. In other words, the etching is performed so that the fill material elements 702, 704 have a desired thickness at the bottom of the openings 500, 502. The etching may for example use bromine, chlorine or fluorine based etching chemistry, or oxygen plasma.

Next, the conductive material 600 is etched using the fill material elements 702, 704 as an etch mask, thereby forming cup-shaped electrically conductive elements 370, 900 within the openings 500, 502 and resulting in the structure illustrated in FIG. 9. For example, the conductive material 600 can be removed with ammonium hydroxide, hydrogen peroxide, and water

Next, the fill material elements 702, 704 are removed, resulting in the structure illustrated in FIG. 10. In the illustrated example, a wet etch process is used to selectively remove the material fill material elements 702, 704. An oxygen plasma etch process may also be used.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A chemical sensor comprising:
a chemically-sensitive field effect transistor including a floating gate conductor having an upper surface;
a dielectric material defining an opening extending to the upper surface of the floating gate conductor; and
a conductive element on a sidewall of the opening and spaced away from an upper surface of the dielectric material, the conductive element communicating with the floating gate conductor.

2. The chemical sensor of claim 1, wherein the conductive element includes an inner surface defining a lower portion of a reaction region for the chemical sensor.

3. The chemical sensor of claim 2, wherein the sidewall of the dielectric material defines an upper portion of the reaction region.

4. The chemical sensor of claim 1, wherein the conductive element extends across the upper surface of the floating gate conductor to define a bottom surface of a reaction region for the chemical sensor.

5. The chemical sensor of claim 1, wherein the conductive element comprises an electrically conductive material, and an inner surface of the conductive element includes an oxide of the electrically conductive material.

6. The chemical sensor of claim 1, further comprising a layer of sensing material on the conductive element.

7. The chemical sensor of claim 6, wherein the sensing material comprises a metal-oxide.

8. The chemical sensor of claim 6, wherein the sensing material is sensitive to hydrogen ions.

9. The chemical sensor of claim 1, wherein the chemically-sensitive field effect transistor includes a floating gate structure comprising a plurality of conductors electrically coupled to one another and separated by dielectric layers, and the floating gate conductor is an uppermost conductor in the plurality of conductors.

10. The chemical sensor of claim 1, wherein the chemically-sensitive field effect transistor generates a sensor signal in response to a chemical reaction occurring proximate to the conductive element.

11. The chemical sensor of claim 10, wherein the chemical reaction is a sequencing reaction.

12. The chemical sensor of claim 1, further comprising a microfluidic structure in fluid flow communication with the chemically-sensitive field effect transistor, and arranged to deliver analytes for sequencing.

13. A method for manufacturing a chemical sensor, the method comprising:
forming a chemically-sensitive field effect transistor including a floating gate conductor having an upper surface;
forming a dielectric material defining an opening extending to the upper surface of the floating gate conductor; and
forming a conductive element on a sidewall of the opening and spaced away from an upper surface of the dielectric material, the conductive element communicating with the floating gate conductor.

14. The method of claim 13, wherein forming the conductive element comprises:
depositing a conductive material on the sidewall of the opening; and
removing the conductive material from an upper portion of the opening.

15. The method of claim 14, wherein removing the conductive material from an upper portion of the opening comprising:
deposing a fill material within the opening;
partially etching the fill material to leave remaining fill material within a lower portion of the opening; and
etching the conductive material using the remaining fill material as an etch mask.

16. The method of claim 13, wherein the conductive element includes an inner surface defining a lower portion of a reaction region for the chemical sensor.

17. The method of claim 16, wherein the sidewall of the dielectric material defines an upper portion of the reaction region.

18. The method of claim 13, wherein forming the conductive element includes forming the conductive element on the upper surface of the floating gate conductor to define a bottom surface of a reaction region for the chemical sensor.

19. A chemical sensor comprising:
an opening defining a reaction region;
a chemically-sensitive field effect transistor including a floating gate in communication with a surface of the cavity; and
a conductive element disposed on an inner portion of the opening, the conductive element communicating a chemical reaction occurring within the cavity to the floating gate.

20. The chemical sensor of claim 19, further comprising a dielectric material defining the cavity.
